(19) United States
(12) Patent Application Publication
(10) Pub. No.: US 2011/0266140 A1
(43) Pub. Date: Nov. 3, 2011

(54) PROCESS FOR PRODUCING REFLECTIVE MASK BLANK FOR EUV LITHOGRAPHY

(75) Inventors: Takeru KINOSHITA, Tokyo (JP); Hirotoshi Ise, Tokyo (JP)

(73) Assignee: ASAHI GLASS COMPANY LIMITED, TOKYO (JP)

(21) Appl. No.: 13/180,611

(22) Filed: Jul. 12, 2011

Related U.S. Application Data
(63) Continuation of application No. PCT/JP10/50985, filed on Jan. 26, 2010.

(30) Foreign Application Priority Data
Jan. 28, 2009 (JP) 2009-016283
Nov. 30, 2009 (JP) 2009-271597
Dec. 14, 2009 (JP) 2009-282872

(51) Int. Cl. C23C 14/06; C23C 14/34

(52) U.S. Cl. 204/192.27

(57) ABSTRACT

Provision of a process for producing an EUV mask blank wherein formation of scars of a glass substrate surface or a chuck surface due to sandwiching of foreign objects such as particles between an electrostatic chuck and the glass substrate, is suppressed.

A process for producing an EUV mask blank wherein an electrostatic chuck for clamping a glass substrate has a main body and a lower dielectric layer made of an organic polymer film, and electrode portion made of an electrically conductive material and an upper dielectric layer made of an organic polymer film provided in this order on the main body, wherein the upper dielectric layer includes an anode and a cathode.

### TECHNICAL FIELD

The present invention relates to a process for producing a reflective mask blank for EUV (Extreme Ultra Violet) lithography to be used for e.g. production of semiconductors (hereinafter referred to as “EUV mask blank” in this specification).

### BACKGROUND ART

In the semiconductor industry, a photolithography method using visible light or ultraviolet light has been employed as a technique for transferring, on a Si substrate or the like, a fine pattern, which is required for forming an integrated circuit comprising such a fine pattern. However, while microsizing of semiconductor devices has been accelerated, the conventional photolithography method has become close to its resolution limit. In the case of light exposure method, it is said that the resolution limit of a pattern is about ½ of an exposure wavelength, and that even if an immersion method is employed, the resolution limit is about ¼ of an exposure wavelength. Even if an immersion method using an ArF laser (193 nm) is employed, it is estimated that the resolution limit is about 45 nm. From this point of view, EUV lithography, which is an exposure technique using EUV light having a shorter wavelength than ArF laser, is considered to be promising as an exposure technique for 45 nm or below. “EUV light” means a ray having a wavelength in a soft X-ray region or a vacuum ultraviolet ray region, specifically a ray having a wavelength of from about 10 to 20 nm, in particular, of about 13.5 nm±0.3 nm.

EUV light is apt to be absorbed by any substances and the refractive indices are close to 1, whereby it is impossible to use a dioptric system like a conventional photolithography employing visible light or ultraviolet light. For this reason, for EUV light lithography, a catoptric system, i.e. a combination of a reflective photomask and mirrors, is employed.

A mask blank is a film-laminated plate for a photomask, which has not been patterned yet. In the case of a mask blank for reflective mask, it has a structure wherein a reflective film for reflecting EUV light and an absorber film for absorbing EUV light, are formed in this order on a substrate made of glass or the like. As the reflective layer, a multilayer reflective film is usually employed, which has alternately laminated high refractive index layers and low refractive index layers so as to increase the light beam reflectance for a light beam incident into a layer surface, more specifically, the light beam reflectance for EUV light incident into a layer surface. For the absorber layer, a material having a high absorption coefficient for EUV light, specifically, for example, a material containing Cr or Ta as the main component is employed. (Refer to e.g. Patent Documents 2 and 3.)

The multilayer reflective film and the absorber layer are formed on an optical surface of the glass substrate by using an ion beam sputtering deposition method or a magnetron sputtering deposition method. At times of forming the multilayer reflective film and the absorber layer, the glass substrate is held by a holding means. As the holding means for the glass substrate, there are a mechanical chuck and an electrostatic chuck, but considering the problem of particle generation, clamping by an electrostatic chuck is preferably employed.

The attraction type of electrostatic chuck is roughly categorized into a monopolar type and a bipolar type. A monopolar type has a mechanism for applying a monopolar voltage and uses e.g. a plasma as an earth to attract a substrate. On the other hand, a bipolar type has a mechanism for applying voltages to an anode and a cathode at the same time in an electrostatic chuck, or a single electrode and an earth mechanism in the electrostatic chuck, whereby the bipolar type can hold a substrate without using e.g. a plasma as an earth.

In a case of using an electrostatic chuck as a means for attracting and holding a glass substrate, since a glass substrate to be clamped is an insulator except for some exception, a bipolar type electrostatic chuck is mostly used.

Electrostatic chucks are roughly categorized into those of Coulomb force type each of which uses an electric charge produced between a substrate and the electrostatic chuck by the difference of dielectric material for attraction, and those of Johnson-Rahbek force type each of which uses an attraction force produced by an electric current leaked from the dielectric film and a difference in a fine irregularity distance on a surface of electrode in addition to the above electric charge. A Coulomb force type electrostatic chuck has a merit that damages and scars of a substrate due to conduction current are small since leakage electric current is small, but it has a demerit that an application voltage is higher than that of a Johnson-Rahbek force type electrostatic chuck.

In a bipolar type electrostatic chuck, besides the above attraction mechanism, its electrode arrangement produces a gradient force attracting an object from a position where the electric field intensity is low to a position where the electric field intensity is high. This force is called as dielectric attraction force.

A glass substrate to be used for a production process of an EUV mask blank is much larger in the size and the mass than a silicon wafer to be employed for a production process of semiconductor devices, and accordingly, exertion of much stronger attraction force than an attraction force of an electrostatic chuck for silicon wafers, is required.

Accordingly, in a case of an electrostatic chuck employed for the purpose of attracting and holding a glass substrate, it is necessary to exert a strong attraction force by a gradient force.

Patent Document 1 proposes an electrostatic chuck which can effectively generate a gradient force to hold a glass substrate by a strong attraction force.

Patent Document 1 describes another problem at a time of holding a glass substrate by an electrostatic chuck. That is, if the substrate is attracted to the electrostatic chuck in a state that fine particles generated by scaring the substrate or other foreign objects are sandwiched between the substrate and the electrostatic chuck, the attraction force may damage a dielectric layer surface being a chuck surface, which may cause such problems that poor flatness of the dielectric layer or poor electric insulation property.

Patent Document 1 describes that the electrostatic chuck of the document is configured to receive a substrate to be attracted closely above an electrode to increase the attractive force of the electrostatic chuck, and further, the electrostatic chuck employs an electrode made of titanium, a compound containing titanium, a titanium oxide or an electrically conductive ceramic such as a titanium nitride or a titanium carbide excellent in abrasive resistance, in order to maintain durability against contact with a substrate to be attracted and rigidity against foreign objects such as particles.

However, when an electrode made of a ceramic material is used as a chuck surface and a glass substrate is attracted to the chuck surface as in the case of the electrostatic chuck described in Patent Document 1, if foreign objects such as particles are sandwiched between the glass substrate and the chuck surface, scars are formed on the glass substrate surface and/or the chuck surface to cause more particles. The scars formed on the chuck surface become sources for continuously transferring the scars to glass substrates contact after formation of the scars, which significantly prevents achievement of low particle generation.

Here, Patent Document 1 describes that the rigidity against foreign objects such as particles can be maintained, but in fact, when foreign objects such as particles are sandwiched between a glass substrate and a chuck surface, scars are formed on the glass substrate surface and/or the chuck surface.

Since such a scar is very small, it has not caused a problem heretofore, but in a case of a glass substrate to be employed for a production process for EUV mask blank, since the requirement to the surface condition is extremely strict, even such a small scar may cause a problem.

### PRIOR ART DOCUMENTS

### Patent Documents

Patent Document 1: JP-A-2006-66857
Patent Document 2: US-A-2007-160874
Patent Document 3: US-A-2009-011341

### DISCLOSURE OF INVENTION

### Technical Problem

In order to solve the above problems of prior art, it is an object of the present invention to provide a process for producing an EUV mask blank whereby generation of scars on a surface of a glass substrate and a chuck surface due to sandwiching of foreign objects such as particles between an electrostatic chuck and a glass substrate.

### Solution to Problem

In order to achieve the above object, the present invention provides a process for producing a reflective mask blank for EUV lithography (EUVL), which comprises forming a reflective layer for reflecting EUV light and an absorber layer for absorbing EUV light in this order on a glass substrate by using a sputtering deposition method while the glass substrate is clamped by an electrostatic chuck;

wherein the electrostatic chuck comprises a main body, and a lower dielectric layer made of an organic polymer film, an electrode portion made of an electrically conductive material and an upper dielectric layer made of an organic polymer film provided in this order on the main body; and wherein the electrode portion includes an anode and a cathode.

Further, the present invention provides a process for producing a reflective mask blank for EUV lithography (EUVL), which comprises forming a reflective layer for reflecting EUV light on a glass substrate and forming an absorber layer for absorbing EUV light on the reflective layer by using a sputtering deposition method while the glass substrate is clamped by an electrostatic chuck;

wherein at least at times of forming the reflective layer and the absorber layer, the electrostatic chuck comprises a main body, and a lower dielectric layer made of an organic polymer film, an electrode portion made of an electrically conductive material and an upper dielectric layer made of an organic polymer film provided in this order on an attraction side surface of the main body; and wherein the electrode portion includes an anode and a cathode.

In the process for producing a reflective mask blank for EUVL of the present invention, the lower dielectric layer of the electrostatic chuck may include at least two layers of organic polymer films.

In the process for producing a reflective mask blank for EUVL of the present invention, the upper dielectric layer of the electrostatic chuck may include at least two layers of organic polymer films.

In the process for producing a reflective mask blank for EUVL of the present invention, each of the lower dielectric layer and the upper dielectric layer of the electrostatic chuck preferably has an insulation breakdown voltage of at least 3.0 kV.

In the process for producing a reflective mask blank for EUVL of the present invention, each of the lower dielectric layer and the upper dielectric layer of the electrostatic chuck preferably has a tensile strength of at least 50 MPa.

In the process for producing a reflective mask blank for EUVL of the present invention, each of the lower dielectric layer and the upper dielectric layer of the electrostatic chuck preferably has a tensile elongation rate of at least 40%.

In the process for producing a reflective mask blank for EUVL of the present invention, each of the lower dielectric layer and the upper dielectric layer of the electrostatic chuck preferably has a tensile modulus of elasticity of at least 1.0 GPa.

In the process for producing a reflective mask blank for EUVL of the present invention, it is preferred that each of the lower dielectric layer and the upper dielectric layer of the electrostatic chuck contains at least one organic polymer film selected from the group consisting of a polyimide film, a polyolefin type material film, a silicone film, a polyvinyl chloride film and a polyethylene terephthalate film.

In the process for producing a reflective mask blank for EUVL of the present invention, it is preferred that the thickness of the lower dielectric layer of the electrostatic chuck is at least twice the thickness of the upper dielectric layer.

In the process for producing a reflective mask blank for EUVL of the present invention, it is preferred that the thickness of the upper dielectric layer of the electrostatic chuck is from 10 to 500 μm.

In the process for producing a reflective mask blank for EUVL of the present invention, it is preferred that the electrostatic chuck has projecting portions on an attraction side surface of the upper dielectric layer so as to reduce the contact area with a glass substrate to be clamped.

The projecting portions are preferably formed by concave-convex shaping of the upper dielectric layer surface by e.g. an etching process. The thickness of the upper dielectric layer after formation of the projecting portions is preferably from 10 to 50 μm.

In the process for producing a reflective mask blank for EUVL of the present invention, it is preferred that the height of the projecting portions of the electrostatic chuck is from 5 to 25 μm.

In the process for producing a reflective mask blank for EUVL of the present invention, it is preferred that the total contact area of the projecting portions of the electrostatic chuck with the glass substrate to be clamped is from 0.1 to 25.0% of the surface area of the upper dielectric member.

In the process for producing a reflective mask blank for EUVL of the present invention, it is preferred that the anode and the cathode of the electrostatic chuck have respective comb-tooth shapes and arranged so that the comb-tooth shapes of respective electrodes are adjacent to each other with a gap.

In the process for producing a reflective mask blank for EUVL of the present invention, it is preferred that the thickness of the electrode portion of the electrostatic chuck is at most 10 μm.

In the process for producing a reflective mask blank for EUVL of the present invention, it is preferred that an electrically conductive film is provided on a surface of the glass substrate to be clamped by the electrostatic chuck.

### Advantageous Effects of Invention

By the process for producing an EUV mask blank of the present invention, it is possible to suppress formation of scars on a surface of a glass substrate and a chuck surface due to sandwiching of foreign objects such as particles between an electrostatic chuck and a glass substrate. Meanwhile, since the layers from the upper dielectric layer to the lower dielectric layer of the electrostatic chuck to be used for clamping a glass substrate have sufficient plasticity and strength, there is no risk that the structure for exerting attraction force is damaged. Further, since it is possible to make the upper dielectric layer sufficiently thin, it is possible to operate the electrostatic chuck with a voltage not preventing stable operation of an apparatus. Further, by providing projecting portions on the attraction side surface of the upper dielectric layer, it is possible to limit portions of sandwiching foreign objects such as particles between the electrostatic chuck and the glass substrate to only the convex portions, thereby to suppress formation of scars due to the sandwiching.

### BRIEF DESCRIPTION OF DRAWINGS

FIG. 1 is a side view showing a construction example of an electrostatic chuck to be used for the process for producing an EUV mask blank of the present invention.

FIG. 2 is a plan view showing an electrostatic chuck 10A shown in FIG. 1

FIG. 3 is a side view showing another construction example of the electrostatic chuck of the present invention.

FIG. 4 is a plan view showing an electrostatic chuck 10B shown in FIG. 3.

FIG. 5 is a side view showing a state that a glass substrate is clamped by using the electrostatic chuck 10A shown in FIG. 1.

### DESCRIPTION OF EMBODIMENTS

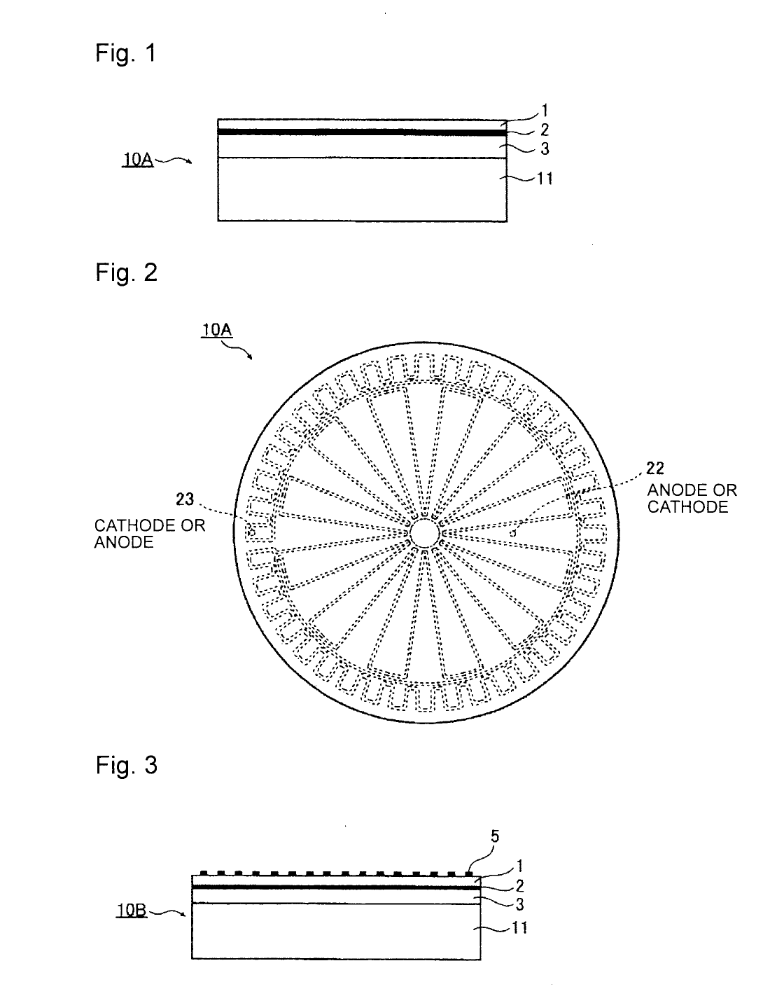

Now, the present invention will be described with reference to drawings. FIG. 1 is a side view showing a construction example of an electrostatic chuck to be used for the process for producing an EUV mask blank of the present invention.

The electrostatic chuck 10A shown in FIG. 1 has a construction wherein on a main body 11, that is on an attraction side surface of the main body, a lower dielectric layer 3 made of an organic polymer film, an electrode portion 2 made of an electrically conductive material and a lower dielectric layer 1 made of an organic polymer film, are provided in this order. Individual constituents of the electrostatic chuck will be described below.

### [Main Body]

The main body 11 of the electrostatic chuck 10A is not particularly limited, and its construction is appropriately selected from known constructions of main body (or substrate or base) of electrostatic chuck. A specific example of such a known structure may be a main body made of a ceramic material such as aluminum oxide (Al₂O₃), yttrium oxide (Y₂O₃), silicon oxide (SiO₂), zirconium oxide (ZrO₂), magnesium oxide (MgO) or mullite (3Al₂O₃.2SiO₂) excellent in insulation property; or a main body constituted by a substrate made of a metal material such as aluminum, molybdenum, tungsten, a steel, a stainless steel, brass or nickel, provided with an insulation layer. As the material of the insulation layer provided on the substrate made of a metal material, the above ceramic material may be mentioned.

### [Electrode Portion]

As a material of the electrode portion, a material excellent in electric conductivity, specifically, a material having a volume resistivity value of at most 5×10⁻⁶ Ωm is employed. Among materials satisfying this criterion, a metal material excellent in electric conductivity, specifically, gold, copper or aluminum is preferred since an electrode portion made of such a material can be made to be a thin layer, and since an electrode pattern having a desired shape can be easily made by a process to be described later.

Among these, gold or copper is preferred for the reason of excellent electric conductivity, copper is particularly preferred for the reason of low price.

The electrostatic chuck 10A is a bipolar type electrostatic chuck having an electrode portion including an anode and a cathode in order to use the chuck for clamping of a glass substrate. Here, the electrode pattern forming the anode and the cathode is not particularly limited, and the pattern may be selected from various types of known electrode patterns in the field of bipolar type electrostatic chuck. However, in order to effectively generate a gradient force to hold a glass substrate by a strong attraction force, for example, it is preferred to form an electrode pattern (refer to FIG. 2) wherein an anode and a cathode each has a comb-tooth shape, and they are disposed so that comb-tooth shapes of respective electrodes are adjacent to each other with a gap as in the electrostatic chuck described in Patent Document 1. FIG. 2 is a plan view of the electrostatic chuck 10A shown in FIG. 1, which shows a preferred electrode pattern in a perspective view.

In FIG. 2, elements indicated by symbols 22 and 23 are holes perforating through the lower dielectric layer and the main body, and external power supply terminals (not shown) are attached through the holes to connect the anode and the cathode to an external power source.

In FIG. 2, dimensions of portions of each electrode pattern is not particularly limited, and they may be appropriately selected according to the dimension of the electrostatic chuck. For example, when the diameter of chuck surface is 13 cm, the width of the comb-tooth shape present in the vicinity of the outer periphery of the chuck surface is 5 mm, its height is 7 mm, and the width of a band-shaped portion constituting the comb-tooth shape is 1 mm.

In the electrostatic chuck 10A, the thickness of the electrode portion is preferably at most 10 μm. Although depending on the thickness of the upper dielectric layer formed on the electrode portion, if the thickness of the electrode portion exceeds 10 μm, a concave-convex shape corresponding to the electrode pattern is formed on the chuck surface of the electrostatic chuck, which may cause decrease of attraction force or unevenness of attraction force. Here, the thickness of the electrode portion is more preferably at most 2 μm, still more preferably at most 1 μm.

However, if the thickness of the electrode portion is far smaller than 1 μm, the insulation breakdown voltage becomes low and the plasticity becomes low to cause breakage at a time of deformation. From this viewpoint, the thickness of the electrode portion is preferably at least 0.1 μm, more preferably at least 0.3 μm, still more preferably at least 0.5 μm.

Here, in order to maintain the flatness and uniformity of the electric resistance, unevenness of the thickness of the electrode portion is preferably within ±10% of the average thickness of the electrode portion.

In the electrostatic chuck 10A, the method for forming the electrode portion is not particularly limited, and a suitable method according to the material of the electrode portion and the electrode pattern, may be appropriately selected. For example, in a case of forming an electrode pattern shown in FIG. 2 by using copper as its material, such an electrode pattern may be formed by forming a thin copper film having a desired thickness on the lower dielectric layer 3 by a sputtering deposition method, and patterning the thin film into a desired electrode pattern by an etching method. Further, also by carrying out a sputtering in a state that a mask having a desired shape is disposed on the lower dielectric layer 3, such an electrode pattern can be formed.

### [Lower Dielectric Layer, Upper Dielectric Layer]

As shown in FIG. 1, the electrostatic chuck 10A has a sandwich structure wherein an electrode portion 2 is sandwiched between a lower dielectric layer 3 and an upper dielectric layer 1, that are organic polymer films.

With such a construction, it is possible to suppress formation of scars on a glass substrate surface and an upper dielectric layer surface forming a chuck surface due to sandwiching of foreign objects such as particles between the electrostatic chuck and the glass substrate. Namely, even in a case where foreign objects such as particles are sandwiched between an upper dielectric layer forming a chuck surface and a glass substrate, flexibility of the upper dielectric layer and the lower dielectric layer, that are organic polymer films, minimizes exposure of the foreign objects to an interface between the glass substrate and the dielectric layer. Accordingly, formation of scars on a glass substrate surface and an upper dielectric layer surface forming a chuck surface, is suppressed.

Hereinafter the effect of suppressing formation of scars on a glass substrate surface and an upper dielectric layer surface forming a chuck surface, is referred to as “function of suppressing scars due to foreign objects”.

There are electrostatic chucks of prior art having an organic polymer film as a dielectric layer formed on an electrode to form a chuck surface, but the thickness of such a dielectric layer is limited since the attraction force decreases when the thickness of the dielectric layer formed on the electrode increases. Accordingly, when foreign objects such as particles are sandwiched between such an electrostatic chuck and a glass substrate, it is not possible to suppress exposure of foreign objects to an interface between a glass substrate and the dielectric layer by the flexibility of the dielectric layer, and accordingly, it has not been possible to exert an effect of suppressing scars due to foreign objects.

In the case of the electrostatic chuck 10A, although the thickness of the upper dielectric layer 1 is limited in the same manner as electrostatic chucks of prior art, the electrostatic chuck has a sandwich structure wherein an electrode portion 2 is sandwiched between a lower dielectric layer 3 and the upper dielectric layer 1 that are organic polymer films. Accordingly, by the flexibility of the lower dielectric layer 3 and the upper dielectric layer 1, exposure of foreign objects to an interface between a glass substrate and the dielectric layer is minimized, whereby it is possible to exert an effect of suppressing scars due to foreign objects without decreasing attraction force.

Moreover, since the attraction force of the electrostatic chuck does not decrease even if the thickness of the lower dielectric layer 3 is increased, it is possible to effectively exert the effect of suppressing scars due to foreign objects by increasing the thickness of the lower dielectric layer 3.

In FIG. 1, the upper dielectric layer 1 and the lower dielectric layer 3 are each shown as a single layer (organic polymer film), but the construction is not limited thereto, and they may be each constituted by at least two organic polymer films.

When the upper dielectric layer 1 and the lower dielectric layer 3 are each constituted by at least two organic polymer films, individual organic films may have different functions. For example, the upper dielectric layer may be constituted by two layers of organic polymer films, wherein an organic polymer facing to the electrode portion may be an organic polymer film excellent in adhesiveness to increase the adhesiveness with the electrode portion, and the other organic polymer film forming a chuck surface may be an organic polymer film excellent in flexibility to increase the effect of suppressing scars due to foreign objects. Further, the lower dielectric layer may be constituted by three layers of organic polymer films, wherein an organic polymer film facing to the electrode portion and an organic polymer film facing to the main body, may be each an organic polymer film excellent in adhesiveness to increase the adhesiveness with the electrode portion and the main body, and an organic polymer film between these films may be an organic polymer film excellent in flexibility to increase the effect of suppressing scars due to foreign objects.

The organic polymer films constituting the upper dielectric layer 1 and the lower dielectric layer 3 preferably satisfy the following properties.

Each of the upper dielectric layer 1 and the lower dielectric layer 3 is required to undergo no insulation breakdown by application of high voltage at a time using the electrostatic chuck. Accordingly, each of the upper dielectric layer 1 and the lower dielectric layer 3 preferably has an insulation breakdown voltage of at least 3.0 kV, more preferably at least 5.0 kV, still more preferably at least 6.0 kV.

Here, when the upper dielectric layer 1 and/or the lower dielectric layer 3 is constituted by at least two organic polymer films, each of organic polymer films constituting the layer preferably has the above insulation breakdown voltage.

Since the organic polymer film constituting the upper dielectric layer 1 forming a chuck surface becomes a particle generation source if it is damaged by scratch with a glass substrate clamped by an electrostatic chuck, the organic polymer film constituting the upper dielectric layer 1 is required to have a sufficient strength against scratching with the glass substrate clamped by the electrostatic chuck. Accordingly, the organic polymer film constituting the upper dielectric layer 1 preferably has a tensile strength of at least 50 MPa, more preferably at least 200 MPa, still more preferably at least 400 MPa.

Further, for the same reason, the organic polymer film constituting the upper dielectric layer 1 preferably has a tensile elongation rate of at least 20%, more preferably at least 30%, still more preferably at least 40%.

Here, when the upper dielectric layer 1 is constituted by at least two organic polymer films, each of the organic polymer films constituting the upper dielectric layer preferably has the above tensile strength and tensile elongation rate.

Also, the organic polymer film constituting the lower dielectric layer 3 is required to have a sufficient tensile strength and tensile elongation rate so as not to be damaged at a time of use of the electrostatic chuck. Accordingly, the organic polymer film constituting the lower dielectric layer 3 preferably has a tensile strength of at least 50 MPa, more preferably at least 200 MPa, still more preferably at least 400 MPa. Further, the organic polymer film constituting the lower dielectric layer 3 preferably has a tensile elongation rate of at least 20%, more preferably at least 30%, still more preferably at least 40%.

Here, when the lower dielectric layer 1 is constituted by at least two layers of organic polymer films, each of the organic polymer films constituting the lower dielectric layer preferably has the above tensile strength and tensile elongation rate.

The organic polymer films constituting the upper dielectric layer 1 and the lower dielectric layer 3 are required to have flexibility for exerting a function of suppressing scars due to foreign objects. The upper dielectric layer 1 forming a chuck surface is required to have an elasticity for increasing contact with a glass substrate to be clamped, and a plasticity for preventing foreign objects bitten into the layer from exposing to an interface with the glass substrate. Accordingly, each of the organic polymer films constituting the upper dielectric layer 1 and the lower dielectric layer 3 preferably has a tensile modulus of elasticity of at least 1.0 GPa, more preferably at least 3.0 GPa, still more preferably at least 7.5 GPa.

Here, when the upper dielectric layer 1 and/or the lower dielectric layer 3 is constituted by at least two organic polymer films, each of the organic polymer films constituting the layer preferably has the above tensile modulus of elasticity.

As an organic polymer film satisfying the above properties, a polyimide film, a polyolefin type material film such as polyethylene or polypropylene, a silicone film, a polyvinyl chloride film or a polyethylene terephthalate film may, for example, be mentioned. Among these, a polyimide film is preferred since it is excellent in all of the above properties.

As described above, the electrostatic chuck 10A has a sandwich structure wherein an electrode portion is sandwiched between a lower dielectric layer and an upper dielectric layer that are organic polymer films, to exert an effect of suppressing scars due to foreign objects. This structure is preferred since increase of the thickness of the lower dielectric layer does not decrease the attractive force of the electrostatic chuck, and by increasing the thickness of the lower dielectric layer, it is possible to exert the function of suppressing scars due to foreign objects without decreasing the attractive force. Accordingly, the thickness of the lower dielectric layer is preferably at least twice the thickness of the upper dielectric layer, more preferably at least three times, still more preferably at least 3.5 times. Further, the thickness of the lower dielectric layer is preferably at most 20 times the thickness of the upper dielectric layer, particularly preferably at most 18 times.

As described above, since increase of the thickness of the upper dielectric layer decreases the attractive force, the thickness of the upper dielectric layer is restricted. Accordingly, the thickness of the upper dielectric layer is preferably at most 500 μm, more preferably at most 100 μm, still more preferably at most 50 μm.

The attractive force increases as the thickness of the upper dielectric layer decreases, but if the thickness of the upper dielectric layer is too small, there may occur such problem as insulation breakdown of the upper dielectric layer or physical breakage of the film. Accordingly, the thickness of the upper dielectric layer is preferably at least 10 μm, more preferably at least 15 μm, still more preferably at least 20 μm, still more preferably at least 25 μm.

The thickness of lower dielectric layer is preferably at least 50 μm for the purpose of exerting the function of suppressing scars due to foreign objects, more preferably at least 80 μm, still more preferably at least 100 μm.

As described above, the attraction force of the electrostatic chuck does not decrease even if the thickness of the lower dielectric layer is increased, but if the thickness of the lower dielectric layer is too large, the flatness of the lower dielectric layer may be deteriorated. As described above, since the electrode portion is a thin film having a preferred thickness of at most 10 μm, if the flatness of the lower dielectric layer being the underlayer of the electrode portion is deteriorated, the electrode portion may be deformed to cause an adversely effect on the function of the electrostatic chuck. Further, if the flatness of the lower dielectric layer is deteriorated, not only the flatness of the electrode portion, but also the flatness of the upper dielectric layer, that is the flatness of the chuck surface of the electrostatic chuck, may be deteriorated. If the flatness of the chuck surface is deteriorated, the attraction force may be deteriorated or the attraction force may become uneven. Accordingly, the thickness of the lower dielectric layer is preferably at most 500 μm, more preferably at most 300 μm, still more preferably at most 200 μm.

Here, the flatness of the chuck surface of the electrostatic chuck is preferably at most 5 μm, more preferably at most 3 μm, still more preferably at most 2 μm. Here, the flatness of the chuck surface can be measured, for example, by using a three-dimensional measurement tool.

Here, in order to obtain a good flatness of the chuck surface, each of the lower dielectric layer and the upper dielectric layer preferably has a thickness distribution (difference between the maximum thickness and the minimum thickness) of at most 5 μm.

The total thickness of the upper dielectric layer and the lower dielectric layer is preferably from 60 to 1,000 μm for the purpose of achieving both exertion of the function of suppressing scars due to foreign objects and other properties of the electrostatic chuck (attraction force, flatness of chuck surface, etc.), more preferably from 65 to 1,000 μm, still more preferably 75 to 800 μm, still more preferably from 100 to 600 μm, still more preferably 150 to 500 μm. The difference between the thickness of the upper dielectric layer and lower dielectric layer is preferably from 50 to 800 μm, particularly preferably from 100 to 300 μm, and the thickness of the lower dielectric layer is preferably thicker than the thickness of the upper dielectric layer.

The method for forming the lower dielectric layer on the main body and the method for forming the upper dielectric layer on the electrode portion are not particularly limited. Since the lower dielectric layer and the upper dielectric layer are organic polymer films, each of them may be formed by forming an organic polymer film having a desired thickness in advance and pasting the formed film onto the main body or the electrode portion by using an adhesive agent or by thermal fusion bonding. Further, it may be formed by directly forming an organic polymer film on the main body or the electrode portion.

FIG. 3 is a side view showing another construction example of an electrostatic chuck to be used for the process for producing an EUV mask blank of the present invention. The electrostatic chuck 10B shown in FIG. 3 is common to the electrostatic chuck 10A shown in FIG. 1 in that it has a sandwich structure wherein an electrode portion 2 is sandwiched between a lower dielectric layer 3 and an upper dielectric layer 1 that are organic polymer films. However, in the electrostatic chuck 10B, a concave-convex process was applied on the upper dielectric layer 1 to have projecting portions 5. By the projecting portions 5, the contact area with a glass substrate to be clamped is reduced. By forming such a construction, it is possible to limit portions where foreign objects such as particles are sandwiched between the electrostatic chuck and a glass substrate only to convex portions, and even if foreign objects are sandwiched at the convex portions, it is possible to suppress formation of scars on the glass substrate surface and the upper dielectric layer surface forming a chuck surface.

The height of the above projecting portion is preferably at least 5 μm, more preferably at least 10 μm in order to make it a meaningful height in relation to the flatness of the chuck main body. The height of the projecting portions 5 is preferably at most 50 μm, more preferably at most 25 μm, further preferably at most 20 μm.

Further, the number of projecting portions is preferably at least 3, more preferably at least 5. The number of projecting portions is preferably at most 15,000, more preferably at most 4,000. The projecting portions are preferably substantially uniformly formed on the attraction surface of the upper dielectric layer.

Further, the total contact area of the above projecting portions with a glass substrate to be clamped is preferably from 0.1 to 25%, particularly preferably from 0.5 to 5% of the surface area of the upper dielectric body.

The projecting portions are preferably formed by a concave-convex process of the upper dielectric layer surface, and the specific process may, for example, be wet etching by using hydrazine.

When the process for producing an EUV mask blank of the present invention is carried out, a rear surface side of a glass substrate for EUV mask blank (rear surface side opposite from an optical surface on which the reflective films and the absorber layer are formed) is clamped. Here, in a case of a glass substrate for EUV mask blank, formation of scars on the rear surface side of the glass substrate causes a problem. Since the electrostatic chuck having the above construction exerts a function of suppressing scars due to foreign objects, the electrostatic chuck is suitable for clamping a glass substrate for EUV mask blank to which requirement of scars on the rear surface side is strict.

In the process for producing an EUV mask blank of the present invention, on a glass substrate clamped by using an electrostatic chuck having the above construction, more specifically, on an optical surface of the glass substrate, at least a reflective layer for reflecting EUV light and an absorber layer for absorbing EUV light are formed in this order by sputtering deposition method(s).

The glass substrate for EUV mask blank is required to have a low thermal expansion coefficient. Specifically, the thermal expansion coefficient at 22° C. is preferably 0±0.1×10⁻⁷/° C., more preferably 0±0.05×10⁻⁷/° C., still more preferably 0±0.03×10⁻⁷/° C. Accordingly, for the glass substrate for EUV mask blank, a glass having a low thermal expansion coefficient, such as a SiO₂—TiO₂ type glass, a crystallized glass produced by precipitating a β quartz solid solution or a quartz glass, etc. is employed.

Further, the glass substrate for EUV mask blank is required to be excellent in smoothness and flatness. Specifically, it preferably has a smooth surface having a surface roughness (rms) or at most 0.15 nm and a flatness of at most 100 nm for the purpose of obtaining high reflectance and high transferring accuracy with a photomask produced by patterning the EUV mask blank.

Further, the glass substrate for EUV mask blank is required to be excellent in durability against a cleaning fluid for e.g. cleaning a mask blank or a photomask produced by patterning the mask blank.

The size and the thickness, etc. of the glass substrate for EUV mask blank are appropriately determined according to e.g. the design values of the mask.

On a rear surface side of the glass substrate for EUV mask blank, a conductive film is preferably formed. In a case of using an electrostatic chuck having the above construction, it is possible to directly clamp a glass substrate having no conductive film formed on the rear surface side. However, when a glass substrate being an insulator and a dielectric body is directly clamped by an electrostatic chuck, it is necessary to apply a high voltage, whereby the glass substrate may undergo insulation breakdown. For this reason, on a rear surface side of a glass substrate to be clamped by the electrostatic chuck, a conductive film is preferably formed.

When a conductive film is formed on a rear surface of a glass substrate, the electric conductivity and the thickness of the material are selected so that the sheet resistance becomes at most 100 ω/□. The material of the conductive film is widely selected from materials described in published documents. For example, a high dielectric coating described in JP-A-2003-501823, specifically, a coating comprising silicon, TiN, molybdenum, chromium or TaSi, may be applied. However, the electrically conductive film is preferably a CrN film, since it has a surface having a small surface roughness and is excellent in contact with a chuck surface and since it has a low sheet resistance and is excellent in chucking force.

The thickness of the electrically conduct film may, for example, be from 10 to 1,000 nm.

The electrically conductive film may be formed by a known film-deposition method, for example, a sputtering deposition method such as a magnetron sputtering deposition method or an ion beam sputtering deposition method, a CVD method, a vacuum vapor deposition method or an electrolytic plating method.

The property particularly required for the reflective layer of the EUV mask blank is high-EUV light beam reflectance. Specifically, when a light beam in the wavelength region of EUV light is incident to the surface of the reflective layer at an incident angle of 6°, the maximum value of the light beam reflectance in the vicinity of wavelength 13.5 nm is preferably at least 60%, more preferably at least 65%. Here, even in a case of providing a protection layer on the reflective layer, the maximum value of the light beam reflectance in the vicinity of wavelength 13.5 nm is preferably at least 60%, more preferably at least 65%.

As the reflective layer, a multilayer reflective film produced by alternately laminating a high refractive index layer and a low refractive index layer a plurality of times is employed since such a multilayer reflective film can achieve a high EUV light beam reflectance. In the multilayer reflective film being a reflective layer, Mo is widely used as each high refractive index layer and Si is widely used as each low refractive index layer. Namely, a Mo/Si multilayer reflective film is the most commonly used. However, the multilayer reflective film is not limited thereto, and a Ru/Si multilayer reflective film, a Mo/Be multilayer reflective film, a Mo compound/Si compound multilayer reflective film, a Si/Mo/Ru multilayer reflective film, a Si/Mo/Ru/Mo multilayer reflective film or Si/Ru/Mo/Ru multilayer reflective film may also be employed.

The film thickness of each layer constituting the multilayer reflective film and the number of repeating units of layer are appropriately selected depending on the film materials to be used and the peak reflectance of the EUV wavelength region required to the multilayer reflective film. In a case of a Mo/Si multilayer reflective film, a multilayer reflective film having a peak reflectance of at least 60% in EUV wavelength region can be produced by laminating a Mo layer having a film thickness of 2.3±0.1 nm and a Si layer having a film thickness of 4.5±0.1 nm in this order so that the repeating unit number becomes 30 to 60.

Here, each layer constituting the multilayer reflective film may be formed by a commonly known film-deposition method such as a magnetron sputtering deposition method or an ion beam sputtering deposition method so as to have a desired film thickness. For example, when a Mo/Si multilayer reflective film is formed by using ion beam sputtering deposition method, it is preferred that a Mo film is formed by using a Mo target as a target and Ar gas (gas pressure 1.3×10⁻² Pa to 2.7×10⁻² Pa) as a sputtering gas under an ion acceleration voltage of from 300 to 1,500 V at a film-deposition rate of 0.03 to 0.30 nm/sec to have a film thickness of 2.3 nm, and subsequently, a Si film is formed by using a Si target as a target and Ar gas (gas pressure 1.3×10⁻² Pa to 2.7×10⁻² Pa) as a sputtering as under an ion acceleration voltage of from 300 to 1,500 V at a film-deposition rate of from 0.03 to 0.30 nm/sec to have a film thickness of 4.5 nm. By repeating such a cycle to laminate 40 to 50 cycles of Mo film and Si film, a Mo/Si multilayer reflective film is formed.

When the reflective layer is a multilayer reflective film, in order to prevent oxidization of the surface of the multilayer reflective film, the uppermost layer of the multilayer reflective film is preferably a layer made of a hardly oxidizable material. The layer made of a hardly oxidizable material will function as a cap layer of the reflective layer. As a specific example of the layer made of a hardly oxidizable material functioning as a cap layer, a Si layer may, for example, be mentioned. In a case where the multilayer reflective film forming the reflective layer 12 is a Mo/Si multilayer reflective film, the uppermost layer may be made to be a Si layer so that the uppermost layer will function as a cap layer. In such a case, the thickness of the cap layer is preferably 11±2 nm.

The property particularly required for the absorber layer is an extremely low EUV light beam reflectance. Specifically, when a light beam in the wavelength region of EUV light is incident to a surface of the absorber layer, the maximum light beam reflectance in the vicinity of wavelength 13.5 nm is preferably at most 0.5% more preferably at most 0.1%.

In order to achieve the above property, the absorber layer is constituted by a material having a high absorption coefficient of EUV light, and is preferably made of a material containing tantalum (Ta) as the main component.

As such an absorber layer, a film containing Ta, B, Si and nitrogen (N) at the following ratio (TaBSiN film) is mentioned.

B content: At least 1 at % and less than 5 at %, preferably from 1 to 4.5 at %, more preferably from 1.5 to 4 at %.

Si content: From 1 to 25 at %, preferably from 1 to 20 at %, more preferably from 2 to 12 at %.

Composition ratio between Ta and N (Ta:N): 8:1 to 1:1.

Ta content: Preferably from 50 to 90 at %, more preferably from 60 to 80 at %.

N content: Preferably from 5 to 30 at %, more preferably from 10 to 25 at %.

An absorber layer having the above composition has an amorphous crystalline state and is excellent in surface smoothness.

The absorber layer having the above construction has a surface roughness of at most 0.5 nm rms. If the surface roughness of the absorber layer surface is large, the edge roughness of a pattern formed in the absorber layer becomes large, whereby the dimension accuracy is deteriorated. Since the influence of edge roughness becomes significant as the pattern is miniaturized, the absorber layer surface is required to be smooth.

When the surface roughness of the absorber layer surface is at most 0.5 nm rms, the absorber layer surface is sufficiently smooth and there is no risk of deterioration of the dimension accuracy of a pattern by the influence of edge roughness. The surface roughness of the absorber layer surface is more preferably at most 0.4 nm rms, still more preferably at most 0.3 nm rms.

The absorber layer having the above construction shows a high etching rate when dry etching is carried out by using a chlorine gas as an etching gas, and shows an etching selectivity of at least 10 to the reflective layer (buffer layer when a buffer layer is formed on the reflective layer). In this specification, the etching selectivity is calculated according to the following formula.

Etching Selectivity=(etching rate of absorber layer)/(etching rate of reflective layer(buffer layer when buffer layer is formed on reflective layer))

The etching selectivity is preferably at least 10, more preferably at least 11, still more preferably at least 12.

The thickness of the absorber layer is preferably from 50 to 100 nm. The absorber layer having the above construction can be formed by using a known film-deposition method, for example, a sputtering deposition method such as a magnetron sputtering deposition method or an ion beam sputtering deposition method. When the magnetron sputtering deposition method is employed, the absorber layer can be formed by any one of the following methods (1) to (3).

(1) A Ta target, a B target and a Si target are employed, and discharges at these targets are carried out simultaneously in an atmosphere of nitrogen (N₂) diluted by Ar to form the absorber layer 15.
(2) A TaB compound target and a Si target are employed, and discharges at these targets are carried out simultaneously in an atmosphere of N₂ diluted by Ar to form the absorber layer.
(3) A TaBSi compound target is employed, and a discharge at the target wherein these three elements are integrated, is carried out in an atmosphere of N₂ diluted by Ar to form the absorber layer.

Here, among the above methods, in the methods ((1) and (2)) of discharging at at least two targets simultaneously, it is possible to control the composition of the absorber layer to be formed, by controlling the input electric power of each target.

Among the above methods, the methods (2) and (3) are preferred for the reason that it is possible to avoid unstability of discharge or variation of the film composition or film thickness, and the method (3) is particularly preferred. The TaBSi compound target particularly preferably has a composition of Ta=50 to 94 at %, Si=5 to 30 at % and B=1 to 20 at % for the reason that it is possible to avoid unstability of discharge or the variation of film composition or film thickness.

The absorber layer can be formed by carrying out the above methods specifically under the following film-deposition conditions.

### Method (2) of Employing TaB Compound Target and Si Target

Sputtering gas: Mixed gas of Ar and N₂ (N₂ gas concentration: 3 to 80 vol %, preferably 5 to 30 vol %, more preferably from 8 to 15 vol %; gas pressure: 1.0×10⁻¹ Pa to 10×10⁻¹ Pa, preferably 1.0×10⁻¹ Pa to 5×10⁻¹ Pa, more preferably 1.0×10⁻¹ Pa to 3×10⁻¹ Pa.).

Input electric power (for each target): 30 to 1,000 W, preferably 50 to 750 W, more preferably 80 to 500 W.

Film-deposition rate: 2.0 to 60 nm/sec, preferably 3.5 to 45 nm/sec, more preferably 5 to 30 nm/sec.

### Method (3) of Employing TaBSi Compound Target

Sputtering gas: Mixed gas of Ar and N₂ (N₂ gas concentration: 3 to 80 vol %, preferably 5 to 30 vol %, more preferably 8 to 15 vol %; gas pressure: 1.0×10⁻¹ Pa to 10×10⁻¹ Pa, preferably 1.0×10⁻¹ Pa to 5×10⁻¹ Pa, more preferably 1.0×10⁻¹ Pa to 3×10⁻¹ Pa.).

Input electric power: 30 to 1,000 W, preferably 50 to 750 W, more preferably 80 to 500 W.

Film-deposition rate: 2.0 to 60 nm/sec, preferably 3.5 to 45 nm/sec, more preferably 5 to 30 nm/sec.

In a case of producing an EUV mask blank, various types of functional layers other than the reflective layer and the absorber layer may be formed. A specific example of such a functional layer is a buffer layer formed as the case requires between the reflective layer and the absorber layer for the purpose of preventing the reflective layer from being damaged at a time of patterning; or a low reflective layer (low reflective layer in the wavelength region of the mask pattern inspection light) formed as the case requires on the absorber layer for the purpose of improving the contrast at the time of mask pattern inspection, may, for example, be mentioned.

The buffer layer is provided for the purpose of protecting a reflective layer so as to prevent the reflective layer from being damaged by an etching process that is usually a dry etching process carried out for patterning the absorber layer. Accordingly, as the material of the buffer layer, a material not susceptible to the etching process of the absorber layer, that is, a material having an etching rate lower than that of the absorber layer and hardly damaged by the etching process, is selected. As a material satisfying this condition, for example, Al, its nitride, Ru, a Ru compound (RuB, RuSi, etc.), SiO₂, Si₃N₄, Al₂O₃ or a mixture of these, may be mentioned. Among these, Ru, a Ru compound (RuB, RuSi, etc.) or SiO₂ is preferred.

Further, the buffer layer preferably contains no Ta and no Cr for the purpose of preventing increase of the film stress. The content of each of Ta and Cr is preferably at most 5 at %, particularly preferably at most 3 at %. Further, the buffer layer preferably contains no Ta and no Cr.

The thickness of the buffer layer is preferably from 1 to 60 nm, particularly preferably from 1 to 10 nm.

The buffer layer is formed by using a known film-deposition method such as a magnetron sputtering deposition method or an ion beam sputtering deposition method. In a case of forming a Ru film by a magnetron sputtering deposition method, it is preferred to carry out film-deposition by using a Ru target as a target and using Ar gas (gas pressure: 1.0×10⁻² Pa to 10×10⁻¹ Pa) as a sputtering gas under an input voltage of from 30 to 1,500 V at a film-deposition rate of from 0.02 to 1.0 nm/sec to have a thickness of from 2 to 5 nm.

In the preparation of a EUV mask, after forming a pattern in the absorber layer, inspection is carried out to ascertain whether the pattern is formed as designed. In such an inspection of a mask pattern, an inspection-machine is usually used wherein light of about 257 nm is used as an inspection light. Namely, inspection is carried out by the difference in the reflectance against such light of about 257 nm, specifically by the difference in the reflectance between the surface exposed by removal of the absorber layer by formation of a pattern and the surface of the absorber layer remained without being removed by the formation of the pattern. Here, the former is the surface of the reflective layer (or the surface of a buffer layer formed on the reflective layer). Accordingly, if the difference in the reflectance between the surface of the reflective layer (or the surface of a buffer layer formed on the reflective layer) and the surface of the absorber layer against the wavelength of the inspection light is small, the contrast at the time of the inspection becomes poor, and no accurate inspection can be done.

The TaBSiN film described as a suitable example of the absorber layer has an extremely low EUV light reflectance and thus has an excellent characteristic as an absorber layer for an EUV mask blank, but when inspected with the wavelength of the inspection light, the light reflectance may not necessarily be said to be sufficiently low. As a result, the difference between the reflectance on the surface of the absorber layer and the reflectance on the surface of the reflective layer (or the surface of a buffer layer formed on the reflective layer) at the wavelength of the inspection light may be small, and the contrast at the time of inspection may not be sufficiently obtained. If the contrast at the time of the inspection is not sufficiently obtained, defects in the pattern cannot sufficiently be identified in the mask inspection, and no accurate inspection of defects can be carried out.

By forming a low reflective layer against the wavelength region of the inspection light on the absorber layer, the contrast at the time of the inspection will be good. In other words, the light reflectance at the wavelength of the inspection light will be very low. In the low reflective layer formed for such a purpose, when the surface of the low reflective layer is irradiated with light in a wavelength region of the inspection light, the maximum light reflectance in the wavelength region of the inspection light is preferably at most 15%, more preferably at most 10%, further preferably at most 5%.

When the maximum light beam reflectance in the wavelength region of the inspection light is at most 15%, the contrast at the time of the inspection is good. Specifically, the contrast between reflected light (reflected light with the wavelength of the inspection light) on the surface of the reflective layer (or the surface of the buffer layer formed on the reflective layer) and reflected light (reflected light with the wavelength of the inspection light) on the surface of the low reflective layer is at least 40%.

In this specification, the contrast can be obtained by using the following formula.

Contrast(%)=((R₂−R₁)/(R₂+R₁))×100

Here, R₂ is the reflectance (the reflectance at the wavelength of the inspection light) on the surface of the reflective layer, and R₁ is the reflectance (the reflectance at the wavelength of inspection light) on the surface of the low reflective layer.

In the present invention, the contrast represented by the above formula is more preferably at least 45%, further preferably at least 60%, particularly preferably at least 80%.

In order to attain the above-described characteristic, the low reflective layer is preferably made of a material having a refractive index at the wavelength of the inspection light being lower than the absorber layer, and its crystalline state is preferably amorphous.

As a specific example of such a low reflective layer, one containing Ta, B, Si and oxygen (O) with the following ratio (low reflective layer (TaBSiO)) is mentioned.

B content: At least 1 at % and less than 5 at %, preferably from 1 to 4.5 at %, more preferably from 1.5 to 4 at %.

Si content: From 1 to 25 at %, preferably from 1 to 20 at %, more preferably from 2 to 10 at %.

Composition ratio between Ta and O (Ta:O): From 7:2 to 1:2, preferably from 7:2 to 1:1, more preferably from 2:1 to 1:1.

Further, as a specific example of the low reflective layer, one containing Ta, B, Si, O and N with the following ratio (low reflective layer (TaBSiON)) is mentioned.

B content: At least 1 at % and less than 5 at %, preferably from 1 to 4.5 at %, more preferably from 2 to 4.0 at %.

Si content: From 1 to 25 at %, preferably from 1 to 20 at %, more preferably from 2 to 10 at %.

Composition ratio between Ta and O and N (Ta:(O+N)): From 7:2 to 1:2, preferably from 7:2 to 1:1, more preferably from 2:1 to 1:1.

When the low reflective layer (TaBSiO) or (TaBSiON) has the above construction, its crystalline state is amorphous, and its surface is excellent in smoothness. Specifically, the surface roughness of the low reflective layer (TaBSiO) or (TaBSiON) is at most 0.5 nm rms.

As described above, in order to prevent deterioration of the dimension accuracy of a pattern due to the influence of edge roughness, the surface of the absorber layer is required to be smooth. Since the low reflective layer is formed on the absorber layer, the surface of the low reflective layer is required to be smooth for the same reason.

When the surface roughness of the low reflective layer is at most 0.5 nm rms, the low reflective layer surface is sufficiently smooth, and there is no risk that the dimension accuracy of a pattern is deteriorated by the influence of edge roughness. The surface roughness of the low reflective layer is more preferably at most 0.4 nm rms, still more preferably at most 0.3 nm rms.

In a case where the low reflective layer is formed on the absorber layer, the total thickness of the absorber layer and the low reflective layer is preferably from 55 to 130 nm. Further, if the thickness of the low reflective layer is larger than the thickness of the absorber layer, the EUV light absorbing characteristic at the absorber layer is likely to deteriorate. Accordingly, the thickness of the low reflective layer is preferably less than the thickness of the absorber layer. Therefore, the thickness of the low reflective layer is preferably from 5 to 30 nm, more preferably from 10 to 20 nm.

The low reflective layer (TaBSiO) or (TaBSiON) can be formed by using a known film-deposition method, for example, a sputtering deposition method such as a magnetron sputtering deposition method or an ion beam sputtering deposition method. In a case of using a magnetron sputtering deposition method, the low reflective layer (TaBSiO) can be formed by any one of the following methods (1) to (3).

(1) A Ta target, a B target and a Si target are employed, and discharges at these targets are carried out simultaneously in an oxygen (O₂) atmosphere diluted by argon (Ar), to form the low reflective layer (TaBSiO).
(2) A TaB compound target and a Si target are employed, and discharges at these targets are carried out simultaneously in an oxygen atmosphere diluted by argon, to form the low reflective layer (TaBSiO).
(3) A TaBSi compound target is employed, and a discharge at the target in which these three elements are integrated, is carried out in an oxygen atmosphere diluted by argon, to form the low reflective layer (TaBSiO).

Here, among the above methods, in the methods ((1) and (2)) of discharging at at least two targets simultaneously, it is possible to control the composition of the low reflective layer (TaBSiO) to be formed, by adjusting the input electric power of each target.

Among the above methods, the methods (2) and (3) are preferred for the reason that it is possible to avoid unstability of discharge or variation in the film composition or the film thickness, and the method of (3) is particularly preferred. The TaBSi compound target particularly preferably has a composition of Ta=50 to 94 at %, Si=5 to 30 at % and B=1 to 20 at % for the reason that it is possible to avoid unstability of discharge or variation of the film composition or the film thickness.

The low reflective layer (TaBSiON) can be formed by carrying out the same procedure as that described above in an oxygen-nitrogen mixed gas atmosphere diluted by argon instead of the oxygen atmosphere diluted by argon.

The low reflective layer (TaBSiO) can be formed by carrying out the above methods specifically under the following film-deposition conditions.

### Method (2) of Employing TaB Compound Target and Si Target

Sputtering gas: mixed gas of Ar and O₂ (O₂ gas concentration: 3 to 80 vol %, preferably 5 to 30 vol %, more preferably 8 to 15 vol %. Gas pressure: 1.0×10⁻¹ Pa to 10×10⁻¹ Pa, preferably 1.0×10⁻¹ Pa to 5×10⁻¹ Pa, more preferably 1.0×10⁻¹ Pa to 3×10^{-1 Pa.).}

Input electric power (for each target): 30 to 1,000 W, preferably 50 to 750 W, more preferably 80 to 500 W.

Film-deposition rate: 2.0 to 60 nm/sec, preferably 3.5 to 45 nm/sec, more preferably 5 to 30 nm/sec.

### Method (3) of Employing TaBSi Compound Target

Sputtering gas: mixed gas of Ar and O₂ (O₂ gas concentration: 3 to 80 vol %, preferably 5 to 30 vol %, more preferably 8 to 15 vol %. Gas pressure: 1.0×10⁻¹ Pa to 10×10⁻¹ Pa, preferably 1.0×10⁻¹ Pa to 5×10⁻¹ Pa, more preferably 1.0×10⁻¹ Pa to 3×10⁻¹ Pa.).

Input electric power: 30 to 1,000 W, preferably 50 to 750 W, more preferably 80 to 500 W.

Film-deposition rate: 2.0 to 50 nm/sec, preferably 2.5 to 35 nm/sec, more preferably 5 to 25 nm/sec.

The low reflective layer (TaBSiON) can be formed by the above method specifically under the following film-deposition conditions.

### Method (2) of Employing TaB Compound Target and Si Target

Sputtering gas: mixed gas of Ar, O₂ and N₂ (O₂ gas concentration: 5 to 30 vol %, N₂ gas concentration: 5 to 30 vol %; preferably O₂ gas concentration: 6 to 25 vol %, N₂ gas concentration: 6 to 25 vol %; more preferably O₂ gas concentration: 10 to 20 vol %, N₂ gas concentration: 15 to 25 vol %. Gas pressure: 1.0×10⁻² Pa to 10×10⁻² Pa, preferably 1.0×10⁻² Pa to 5×10⁻² Pa, more preferably 1.0×10⁻² Pa to 3×10⁻² Pa.).

Input electric power (for each target): 30 to 1,000 W, preferably 50 to 750 W, more preferably 80 to 500 W.

Film-deposition rate: 2.0 to 50 nm/sec, preferably 2.5 to 35 nm/sec, more preferably 5 to 25 nm/sec.

### Method (3) of Employing TaBSi Compound Target

Sputtering gas: mixed gas of Ar, O₂ and N₂ (O₂ gas concentration: 5 to 30 vol %, N₂ gas concentration: 5 to 30 vol %; preferably O₂ gas concentration: 6 to 25 vol %, N₂ gas concentration: 6 to 25 vol %; more preferably O₂ gas concentration: 10 to 20 vol %, N₂ gas concentration: 15 to 25 vol %. Gas pressure: 1.0×10⁻² Pa to 10×10⁻² Pa, preferably 1.0×10⁻² Pa to 5×10⁻² Pa, more preferably 1.0×10⁻² Pa to 3×10⁻² Pa.).

Input electric power: 30 to 1,000 W, preferably 50 to 750 W, more preferably 80 to 500 W.

Film-deposition rate: 2.0 to 50 nm/sec, preferably 2.5 to 35 nm/sec, more preferably 5 to 25 nm/sec.

Further, it is preferred to form the low reflective layer on the absorber layer, because the wavelength of light for inspection of a pattern is different from the wavelength of EUV light. Accordingly, in a case where EUV light (in the vicinity of 13.5 nm) is used as light for inspection of a pattern, it is considered unnecessary to form a low reflective layer on the absorber layer. The wavelength of the inspection light tends to shift to the short wavelength side as the pattern dimension becomes small and in future, it may shift to 193 nm or further shift to 13.5 nm. When the wavelength of the inspection light is 13.5 nm, it will not be necessary to form the low reflective layer on the absorber layer.

### EXAMPLES

Now, the present invention will be further described with reference to Examples.

### Example 1

In Example 1, an electrostatic chuck 10A shown in FIGS. 1 and 2 was employed. The electrostatic chuck 10A was prepared in the following procedure.

On a main body 11 made of alumina, a polyimide film having a thickness of 125 μm was heated to be fusion-bonded to form a lower dielectric layer 3.

Electrode holes 22 and 23 are provided to perforate through the lower dielectric layer 3 and the main body 11 as shown in FIG. 2 to connect an electrode portion 2 to an external power source, and the electrode portion 2 is connected to external electrode terminals through the electrode holes 22 and 23.

On the lower electrode layer 3, a copper thin film having a thickness of 1 μm was formed by a sputtering deposition method, and an etching was carried out through a mask having a desired shape to form an electrode portion 2 having an electrode pattern shown in FIG. 2.

Next, on the electrode portion 2, a polyimide film having a thickness of 50 μm was heated to be fusion-bonded to form an upper dielectric layer 1. Even by the heating for fusion-bonding, the thickness of the polyimide film was not changed. Here, e.g. physical properties of the polyimide films employed as the upper dielectric layer 1 and the lower dielectric layer 3 are as follows.

Insulation breakdown voltage: 6.8 kV

Tensile strength: 520 MPa

Tensile elongation rate: 42%

Tensile modulus of elasticity: 9.1 GPa

The magnification ratio of the thickness of the lower dielectric layer to the thickness of the upper dielectric layer: 125 μm/50 μm=2.5

Further, the chuck surface of the electrostatic chuck was a circular shape having a diameter of 13 cm.

As shown in FIG. 5, by employing the electrostatic chuck 10A prepared in the above procedure, a glass substrate for EUV mask blank was clamped, and a reflective layer for reflecting EUV light, a buffer layer, an absorber layer for absorbing EUV light were formed in this order on the glass substrate by a sputtering deposition method. A glass substrate 30 is a zero-expansion glass containing SiO₂ as the main component, and it has a thermal expansion coefficient of 0/° C. at 22° C.

On the clamping surface side of the glass substrate 30, an electrically conductive film 40 is deposited. The electrically conductive film 40 is a chromium nitride (CrN) film having a thickness of 70 nm and having a sheet resistance of 90 ω/□.

The voltage between the electrodes of the electrostatic chuck was set to be 1,000 V, and the electrostatic chuck held the glass substrate for 2 hours in a vacuum having a pressure of 2.0×10⁻⁴ torr while the electrostatic chuck was rotated at 30 rμm.

The number of defects on the clamping surface of the glass substrate was measured before and after the clamping. Specifically, with a commercially available defect inspection apparatus (M1350 manufactured by Lasertec Corporation), the number of defects of at least 200 nm was measured in a 142 mm square inspection region. As a result, the number of defects increased during the clamping was 1.0×10³ pieces.

The clamping of the glass substrate was repeated ten times in the same manner, but no decrease of the attraction force of the electrostatic chuck occurred.

### Example 2

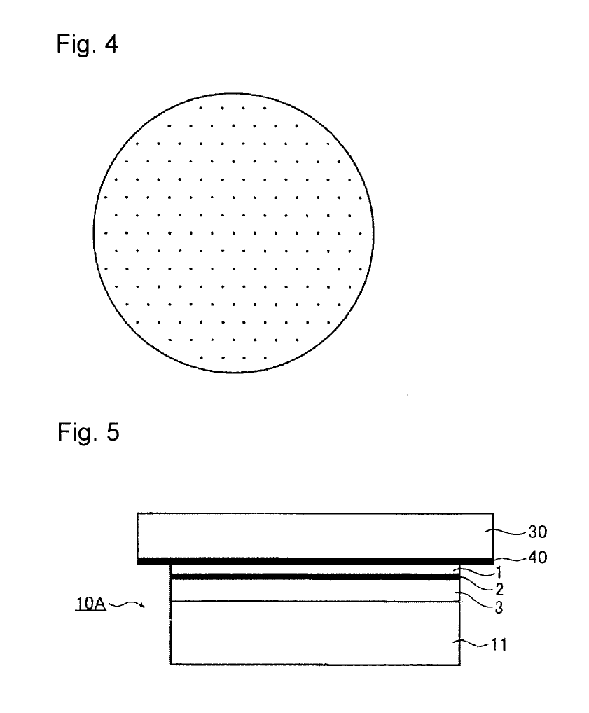

In Example 2, an electrostatic chuck 10B shown in FIG. 3 was employed. The electrostatic chuck 10B was prepared by carrying out the preparation process of the above electrostatic chuck 10A, attaching to the above dielectric layer 1 a mask having a desired concave and convex pattern, and carrying out a wet etching by using hydrazine to form projecting portions 5. The pattern of the projecting portions is as shown in FIG. 4, and the pattern was adjusted so that the total surface area of the projecting portions became 1% of the surface area of the upper dielectric layer 1 before wet etching. Further, the height of the projecting portions was set to be 10 μm. Accordingly, a portion of the upper dielectric layer 1 having no projecting portion became 40 μm.

By using the prepared electrostatic chuck 10B, clamping of a glass substrate was carried out in the same manner as Example 1. The number of defects increased by the clamping was 1.0×10⁻² pieces.

In the same manner as Example 1, the clamping of glass substrate was repeated 10 times, but no decrease of the attraction force of the electrostatic chuck occurred.

### Example 3

In Example 3, each of the lower dielectric layer and the upper dielectric layer are formed by two respective polyimide films. An electrostatic chuck 10A shown in FIGS. 1 and 2 was prepared. The electrostatic chuck 10A was prepared in the following process.

On a main body 11 made of an alumina, two polyimide films each having a thickness of 125 μm were laminated and heated to be fusion-bonded to form a lower dielectric layer 3. The purpose of laminating two films to make the thickness twice as thick is to increase the mechanical durability by increasing the thickness.

Electrode holes 22 and 23 are provided to perforate through the lower dielectric layer 3 and the main body 11 to connect an electrode portion 2 to an external power source as shown in FIG. 2, and the electrode portion 2 is connected to external electrode terminals through the electrode holes 22 and 23.

On the lower electrode layer 3, a copper thin film having a thickness of 1 μm was formed by a sputtering deposition method, and an etching was carried out via a mask having a desired shape to form an electrode portion 2 having an electrode pattern shown in FIG. 2.

Next, on the electrode portion 2, two polyimide films each having a thickness of 7.5 μm were laminated and heated to be fusion-bonded to form an upper dielectric layer 1. The purpose of laminating two films is to obtain an upper dielectric layer having a desired thickness.

Here, the physical properties of the polyimide films employed for the upper dielectric layer 1 and the lower dielectric layer 3 are as follows.

Insulation breakdown voltage: 6.8 kV

Tensile strength: 520 MPa

Tensile elongation rate: 42%

Tensile modulus of elasticity: 9.1 GPa

The magnification ratio of the thickness of the lower dielectric layer to the thickness of the upper dielectric layer: 250 μm/15 μm=16.7

Further, the chuck surface of the electrostatic chuck was a circular shape having a diameter of 13 cm.

### Comparative Example 1

By employing a conventional electrostatic chuck having a Al₂O₃ clamping surface, that is an electrostatic chuck wherein the dielectric layers 1 and 3 and the main body 11 of the electrostatic chuck 10A of FIG. 1 was integrally formed with Al₂O₃, clamping of a glass substrate was carried out in the same manner as Examples. The number of defects increased by the clamping was 1.0×10⁴ pieces, which was worse by one digit than Example 1 and worse by two digits than Example 2.

### Comparative Example 2

An electrostatic chuck having a construction of Example 1 from which the lower dielectric layer 3 was removed was prepared, and clamping of a glass substrate was carried out in the same manner as Example 1. When clamping of the glass substrate was repeated 10 times, the attraction force was disappeared. It is considered that by sandwiching foreign objects such as particles between the electrostatic chuck and the glass substrate, a polyimide film being the upper dielectric layer 1 was perforated to cause a complete or a non-complete short circuit between the electrode portion 2 and the electrically conductive film 40, and such short circuit causes disappearance of electric potential difference or causes abnormal discharge to lose the attraction force. It is substantially impossible to practically use an electrostatic chuck whose attraction force disappears by 10 times of clamping operation.

### Comparative Example 3

An electrostatic chuck having a construction of Example 2 from which the lower dielectric layer 3 was removed was prepared, and clamping of a glass substrate was carried out in the same manner as Example 2. When clamping of the glass substrate was repeated 10 times, the attraction force was disappeared. It is considered that by sandwiching foreign objects such as particles between the electrostatic chuck and the glass substrate, a polyimide film being the upper dielectric layer 1 was perforated to cause a complete or a non-complete short circuit between the electrode portion 2 and the electrically conductive film 40, and such short circuit causes disappearance of electric potential difference or causes abnormal discharge to lose the attraction force. It is substantially impossible to practically use an electrostatic chuck whose attraction force disappears by 10 times of clamping operation.

From the comparison of Examples 1, 2 and Comparative Examples 1 to 3, it is apparent that the electrostatic chuck of the present invention is practically usable and generates less particles.

### Example 4

In this Example, an EUV mask blank is prepared in the following process.

By using an electrostatic chuck 10A used in Example 1, a glass substrate is clamped. The glass substrate is a zero-expansion glass containing SiO₂ as the main component, and has a thermal expansion coefficient of 0/° C. at 22° C. On the clamping surface side of the glass substrate, an electrically conductive film is formed. The electrically conductive film is a chromium nitride (CrN) film having a sheet resistance of 90 ω/□ and a thickness of 70 nm.

On the optical surface of the glass substrate, alternate deposition of Mo film and Si film is repeated 50 cycles by using an ion beam sputtering deposition method to form a Mo/Si multilayer reflective film having a total film thickness of 340 nm ((2.3 nm+4.5 nm)×50).

The film-disposition conditions of the Mo film and the Si film are as follows.

### Film-Deposition Conditions of Mo Film

Target: Mo target

Sputtering gas: Ar gas (gas pressure: 0.02 Pa)

Voltage: 700 V

Film-deposition rate: 0.064 nm/sec

Film thickness: 2.3 nm

### Film-Deposition Conditions of Si Film

Target: Si target (boron-doped)

Sputtering gas: Ar gas (gas pressure: 0.02 Pa)

Voltage: 700 V

Film-deposition rate: 0.077 nm/sec

Film thickness: 4.5 nm

Next, on the Mo/Si multilayer reflective film, as a buffer layer, a Ru layer is formed by using an ion beam sputtering deposition method.

The deposition conditions of the buffer layer are as follows.

Target: Ru target

Sputtering gas: Ar gas (gas pressure: 0.02 Pa)

Voltage: 700 V

Film-deposition rate: 0.052 nm/sec

Film thickness: 2.5 nm

Next, on a protection layer, as an absorber layer, a TaBSiN layer is formed by a magnetron sputtering deposition method.

Film-deposition conditions of the TaBSiN layer are as follows.

### Film-Deposition Conditions of TaBSin Layer

Target: TaBSi compound target (composition ratio: Ta 80 at %, B 10 at %, Si 10 at %)

Sputtering gas: Mixed gas of Ar and N₂ (Ar: 86 vol %, N₂: 14 vol %, gas pressure: 0.3 Pa)

Input power: 150 W

Film-deposition rate: 0.12 nm/sec

Film thickness: 60 nm

Next, on the absorber layer, as a low reflective layer, a TaBSiON layer is formed by a magnetron sputtering deposition method to obtain an EUV mask blank wherein a Mo/Si multilayer reflective film, a Ru layer, a TaBSiN layer and a TaBSiON layer are formed in this order on a substrate.

The film-deposition conditions of the TaBSiON film are as follows.

### The Film-Deposition Conditions of the TaBSiOn Layer

Target: TaBSi target (composition ratio: Ta 80 at %, B 10 at %, Si 10 at %)

Sputtering gas: Mixed gas of Ar, N₂ and O₂ (Ar: 60 vol %, N₂: 20 vol %, O₂: 20 vol %, gas pressure: 0.3 Pa)

Input power: 150 W

Film-deposition rate: 0.18 nm/sec

Film thickness: 10 nm

It is confirmed that an EUV mask blank prepared by the above process has few defects and is a mask blank suitable for an EUV mask.

### Example 5

In this Example, an EUV mask blank wherein a Mo/Si multilayer reflective film, a Ru layer, a TaBSiN layer and a TaBSiON layer are formed in this order on a substrate is obtained in the same manner as Example 4 except that the electrostatic chuck 10B used in Example 2 is used as an electrostatic chuck for clamping the glass substrate. It is confirmed that an obtained EUV mask blank has few defects and is a mask blank suitable for an EUV mask.

### INDUSTRIAL APPLICABILITY

In the present invention, it is possible to hold a glass substrate with a sufficient clamping force by an electrostatic chuck at a time of depositing films on the glass substrate, and to suppress formation of scars on a glass substrate surface and a chuck surface due to sandwiching of foreign objects such as particles between the electrostatic chuck and the glass substrate. Accordingly, the present invention is suitably usable for a process for producing an EUV mask blank wherein generation of slight scars is regarded as a significant problem.

The entire disclosures of Japanese Patent Application No. 2009-016283 filed on Jan. 28, 2009, Japanese Patent Application No. 2009-271597 filed on Nov. 30, 2009 and Japanese Patent Application No. 2009-282872 filed on Dec. 14, 2009 including specifications, claims, drawings and summaries are incorporated herein by reference in their entireties.

### REFERENCE SYMBOLS

1: upper dielectric layer
2: electrode portion
3: lower dielectric layer
5: projecting portion
10A, 10B: electrostatic chuck
11: main body
30: glass substrate
40: electrically conductive film

What is claimed is:

1. A process for producing a reflective mask blank for EUV lithography (EUVL), which comprises forming a reflective layer for reflecting EUV light and an absorber layer for absorbing EUV light in this order on a glass substrate by using a sputtering deposition method while the glass substrate is clamped by an electrostatic chuck;
wherein the electrostatic chuck comprises a main body, and a lower dielectric layer made of an organic polymer film, an electrode portion made of an electrically conductive material and an upper dielectric layer made of an organic polymer film provided in this order on the main body; and wherein the electrode portion includes an anode and a cathode.

2. A process for producing a reflective mask blank for EUV lithography (EUVL), which comprises forming a reflective layer for reflecting EUV light on a glass substrate and forming an absorber layer for absorbing EUV light on the reflective layer by using a sputtering deposition method while the glass substrate is clamped by an electrostatic chuck;
wherein at least at times of forming the reflective layer and the absorber layer, the electrostatic chuck comprises a main body, and a lower dielectric layer made of an organic polymer film, an electrode portion made of an electrically conductive material and an upper dielectric layer made of an organic polymer film provided in this order on an attraction side surface of the main body; and wherein the electrode portion includes an anode and a cathode.

3. The process for producing a reflective mask blank for EUVL according to claim 1, wherein the lower dielectric layer of the electrostatic chuck includes at least two layers of organic polymer films.

4. The process for producing a reflective mask blank for EUVL according to claim 2, wherein the lower dielectric layer of the electrostatic chuck includes at least two layers of organic polymer films.

5. The process for producing a reflective mask blank for EUVL according to claim 1, wherein the upper dielectric layer of the electrostatic chuck includes at least two layers of organic polymer films.

6. The process for producing a reflective mask blank for EUVL according to claim 2, wherein the upper dielectric layer of the electrostatic chuck includes at least two layers of organic polymer films.

7. The process for producing a reflective mask blank for EUVL according to claim 1, wherein each of the lower dielectric layer and the upper dielectric layer of the electrostatic chuck has an insulation breakdown voltage of at least 3.0 kV.

8. The process for producing a reflective mask blank for EUVL according to claim 2, wherein each of the lower dielectric layer and the upper dielectric layer of the electrostatic chuck has an insulation breakdown voltage of at least 3.0 kV.

9. The process for producing a reflective mask blank for EUVL according to claim 1, wherein each of the lower dielectric layer and the upper dielectric layer of the electrostatic chuck has a tensile strength of at least 50 MPa.

10. The process for producing a reflective mask blank for EUVL according to claim 2, wherein each of the lower dielectric layer and the upper dielectric layer of the electrostatic chuck has a tensile strength of at least 50 MPa.

11. The process for producing a reflective mask blank for EUVL according to claim 1, wherein each of the lower dielectric layer and the upper dielectric layer of the electrostatic chuck has a tensile elongation rate of at least 20%.

12. The process for producing a reflective mask blank for EUVL according to claim 2, wherein each of the lower dielectric layer and the upper dielectric layer of the electrostatic chuck has a tensile elongation rate of at least 20%.

13. The process for producing a reflective mask blank for EUVL according to claim 1, wherein each of the lower dielectric layer and the upper dielectric layer of the electrostatic chuck has a tensile modulus of elasticity of at least 1.0 GPa.

14. The process for producing a reflective mask blank for EUVL according to claim 2, wherein each of the lower dielectric layer and the upper dielectric layer of the electrostatic chuck has a tensile modulus of elasticity of at least 1.0 GPa.

15. The process for producing a reflective mask blank for EUVL according to claim 1, wherein each of the lower dielectric layer and the upper dielectric layer of the electrostatic chuck contains at least one organic polymer film selected from the group consisting of a polyimide film, a polyolefin type material film, a silicone film, a polyvinyl chloride film and a polyethylene terephthalate film.

16. The process for producing a reflective mask blank for EUVL according to claim 2, wherein each of the lower dielectric layer and the upper dielectric layer of the electrostatic chuck contains at least one organic polymer film selected from the group consisting of a polyimide film, a polyolefin type material film, a silicone film, a polyvinyl chloride film and a polyethylene terephthalate film.

17. The process for producing a reflective mask blank for EUVL according to claim 1, wherein the thickness of the lower dielectric layer of the electrostatic chuck is at least twice the thickness of the upper dielectric layer.

18. The process for producing a reflective mask blank for EUVL according to claim 2, wherein the thickness of the lower dielectric layer of the electrostatic chuck is at least twice the thickness of the upper dielectric layer.

19. The process for producing a reflective mask blank for EUVL according to claim 1, wherein the thickness of the upper dielectric layer of the electrostatic chuck is from 10 to 500 μm.

20. The process for producing a reflective mask blank for EUVL according to claim 2, wherein the thickness of the upper dielectric layer of the electrostatic chuck is from 10 to 500 μm.

21. The process for producing a reflective mask blank for EUVL according to claim 1, wherein the electrostatic chuck has projecting portions on an attraction side surface of the upper dielectric layer so as to reduce the contact area with a glass substrate to be clamped.

22. The process for producing a reflective mask blank for EUVL according to claim 2, wherein the electrostatic chuck has projecting portions on an attraction side surface of the upper dielectric layer so as to reduce the contact area with a glass substrate to be clamped.

23. The process for producing a reflective mask blank for EUVL according to claim 21, wherein the height of the projecting portions of the electrostatic chuck is from 5 to 50 μm.

24. The process for producing a reflective mask blank for EUVL according to claim 22, wherein the height of the projecting portions of the electrostatic chuck is from 5 to 50 μm.

25. The process for producing a reflective mask blank for EUVL according to claim 21, wherein the total contact area of the projecting portions of the electrostatic chuck with the glass substrate to be clamped is from 0.1 to 25.0% of the surface area of the upper dielectric member.

26. The process for producing a reflective mask blank for EUVL according to claim 22, wherein the total contact area of the projecting portions of the electrostatic chuck with the glass substrate to be clamped is from 0.1 to 25.0% of the surface area of the upper dielectric member.

27. The process for producing a reflective mask blank for EUVL according to claim 1, wherein the anode and the cathode of the electrostatic chuck have respective comb-tooth shapes and arranged so that the comb-tooth shapes of respective electrodes are adjacent to each other with a gap.

28. The process for producing a reflective mask blank for EUVL according to claim 2, wherein the anode and the cathode of the electrostatic chuck have respective comb-tooth shapes and arranged so that the comb-tooth shapes of respective electrodes are adjacent to each other with a gap.

29. The process for producing a reflective mask blank for EUVL according to claim 1, wherein the thickness of the electrode portion of the electrostatic chuck is at most 10 μm.

30. The process for producing a reflective mask blank for EUVL according to claim 2, wherein the thickness of the electrode portion of the electrostatic chuck is at most 10 μm.

31. The process for producing a reflective mask blank for EUVL according to claim 1, wherein an electrically conductive film is provided on a surface of the glass substrate to be clamped by the electrostatic chuck.

32. The process for producing a reflective mask blank for EUVL according to claim 2, wherein an electrically conductive film is provided on a surface of the glass substrate to be clamped by the electrostatic chuck.
